(19) United States
(12) Patent Application Publication
(10) Pub. No.: US 2026/0072084 A1
(43) Pub. Date: Mar. 12, 2026

(54) FAULT DETECTION IN SYNCHRONOUS MACHINES USING PATTERN RECOGNITION

(71) Applicant: NORWEGIAN UNIVERSITY OF SCIENCE AND TECHNOLOGY (NTNU), Trondheim (NO)

(72) Inventor: Hossein EHYA, Trondheim (NO)

(21) Appl. No.: 19/107,833

(22) PCT Filed: Aug. 31, 2023
(86) PCT No.: PCT/EP2023/073955

§ 371 Date: Feb. 28, 2025

(30) Foreign Application Priority Data
Sep. 2, 2022 (GB) 2212828.4

(51) Int. Cl. G01R 31/34; G01R 23/16; G01R 33/06; H02K 11/20

(52) U.S. Cl. CPC G01R 31/343; G01R 23/16; G01R 31/346; G01R 33/06; H02K 11/20

(57) ABSTRACT

A method of fault detection in a synchronous machine is provided. The method comprises: using at least one sensor to determine a measure of a stray magnetic field generated by the synchronous machine; processing the determined measure in order to obtain a frequency spectrum for the stray magnetic field; analysing the frequency spectrum for the stray magnetic field in order to identify a predetermined pattern, characteristic of one or more fault conditions, within the frequency spectrum; and determining one or more faults within the synchronous machine based on identifying the pattern.

### TECHNICAL FIELD

The present invention relates to methods of fault detection in synchronous machines, as well as to related fault detection systems, which may be combined with a synchronous machine, and to corresponding computer programs.

### BACKGROUND

Synchronous machines are used widely for many different purposes. Providing secure electricity depends on the reliable operation of synchronous generators in power plants, for example. However synchronous machine can experience faults. For example, inter-turn short circuit (ITSC) and dynamic eccentricity (DE) faults are among the most prevalent fault types in wound field synchronous generators (WFSGs).

Embodiments of the present invention seek to provide improved approaches to fault detection in synchronous machines.

### SUMMARY OF THE INVENTION

Viewed from a first aspect, the invention provides a method of fault detection in a synchronous machine, the method comprising using at least one sensor to determine a measure of a stray magnetic field generated by the synchronous machine, and processing the determined measure to obtain a frequency spectrum for the stray magnetic field. The frequency spectrum for the stray magnetic field is analysed in order to identify a predetermined pattern, characteristic of one or more fault conditions, within the frequency spectrum. One or more faults are determined (e.g. detected or identified) within the synchronous machine based on this identifying of the pattern.

Thus it will be seen that, in accordance with embodiments of the invention, spectral analysis of the stray magnetic field can enable a fault to be detected based on the identification of a predetermined pattern in the spectrum. This use of a predetermined pattern means that, at least in some embodiments, there is no need to collect a reference spectrum from a specific synchronous machine, under a non-fault condition, for use in a comparison with a later-obtained spectrum from the same synchronous machine. Instead, at least in some embodiments, the predetermined pattern may be used across many different synchronous machines, e.g. regardless of their power rating and topologies.

The one or more faults may include an inter-turn short circuit fault, or a dynamic eccentricity fault, or a short-circuit fault, or a static eccentricity fault, or a misalignment, or a demagnetization fault, or a combination of two or more such faults.

The synchronous machine may be a wound field synchronous machine or may be a permanent-magnet synchronous machine.

The synchronous machine may be a synchronous generator, optionally for a hydropower plant.

The at least one sensor may include a search coil. The search coil may be located on or adjacent a stator core back side or a frame of the synchronous machine. The at least one sensor may comprise exactly one search coil.

The at least one sensor may include at least one non-invasive sensor.

The method may be suitable for an internet-of-things (IoT) solution.

The method may be for early-stage fault detection.

The method may be carried out during no-load and/or full-load operation of the synchronous machine.

The method may comprise determining that no fault exists if no predetermined pattern, characteristic of one or more fault conditions, can be identified within the frequency spectrum for the stray magnetic field.

The identified pattern may be independent of the power rating and/or the topology of the synchronous machine.

The method may comprise using a machine learning algorithm to identify the predetermined pattern.

Analysing the frequency spectrum may comprise determining whether the frequency spectrum matches one of two or more different predetermined patterns, each predetermined pattern being characteristic of a different respective fault condition, such as an inter-turn short circuit fault or a dynamic eccentricity fault respectively.

The method may comprise signalling a detection of the one or more faults to an output device, such as a display, or over a network connection.

The stray magnetic field may be a combination of radial and axial magnetic fields.

The measure may represent a strength of the stray magnetic field over time.

The predetermined pattern may be a pattern of amplitudes of respective frequency components within the frequency spectrum.

The frequency components may be determined in accordance with a predetermined function of a stator terminal frequency, fs, of the synchronous machine and/or the number of rotor poles in the synchronous machine.

The predetermined pattern may comprise an increasing sequence of amplitudes between fs and twice fs, and a decreasing sequence of amplitudes between twice fs and three times fs, wherein the predetermined pattern may be characteristic of an inter-turn short circuit fault.

The predetermined pattern may comprise a decreasing sequence of amplitudes between fs and twice fs, and an increasing sequence of amplitudes between twice fs and three times fs, and the predetermined pattern may be characteristic of a dynamic eccentricity fault.

The predetermined pattern may comprise the amplitudes of frequency components between fs and twice fs all being within a predetermined maximum range, and the predetermined pattern may be characteristic of a combined inter-turn short circuit fault and dynamic eccentricity fault.

Processing the received measure to obtain the frequency spectrum may comprise applying frequency-domain signal processing, such as a fast Fourier transform, to the received measure.

Viewed from a second aspect, the invention provides a fault detection system for fault detection in synchronous machines, the fault detection system comprising a data processing apparatus configured to receive a measure of a stray magnetic field generated by the synchronous machine; wherein the data processing apparatus is configured to: process the received measure in order to obtain a frequency spectrum for the stray magnetic field; analyse the frequency spectrum for the stray magnetic field in order to identify a predetermined pattern, characteristic of one or more fault conditions, within the frequency spectrum; and determine one or more faults within the synchronous machine based on identifying the pattern.

The data processing apparatus may be configured to perform the method of the first aspect, including any optional features of the method of the first aspect disclosed herein.

The data processing apparatus may be or may comprise a microcontroller.

The data processing apparatus may be or may comprise a field programmable gate array.

The fault detection system may further comprise at least one sensor for determining the measure of the stray magnetic field.

The fault detection system of the second aspect may be part of, or combined with, a synchronous machine.

The synchronous machine may be a synchronous generator.

Some embodiments may be for detecting a fault in a wound field synchronous machine.

Some embodiments may be for detecting faults in a permanent-magnet synchronous machine.

The fault detection system may be configured to detect an inter-turn short circuit fault and/or to detect a dynamic eccentricity fault and/or to detect a short-circuit fault and/or to detect a static eccentricity fault and/or to detect a misalignment and/or to detect a demagnetization fault and/or to detect any combination of two or more such faults. The fault detection system may be configured to distinguish between two or more fault conditions. It may be configured to signal what type of fault or combination of faults have been detected.

In particular, in some embodiments, the fault detection system is configured to detect an inter-turn short circuit fault and is also configured to detect a dynamic eccentricity fault. It may be further configured to detect a combination of an inter-turn short circuit fault and a dynamic eccentricity fault (i.e. occurring simultaneously).

In embodiments where the synchronous machine is a permanent-magnet synchronous machine, the one or more faults may include a demagnetization fault (either alone or optionally in combination with one or more other types of fault, such as a short-circuit fault, an eccentricity fault, and/or a misalignment).

In some embodiments, the predetermined pattern is identified only from the frequency spectrum—i.e. without any additional time-domain processing.

Viewed from a third aspect, the invention provides a computer program comprising instructions that, when executed on a data processing apparatus will cause the data processing apparatus to: process a received measure of a stray magnetic field generated by a synchronous machine in order to obtain a frequency spectrum for the stray magnetic field; analyse the frequency spectrum for the stray magnetic field in order to identify a predetermined pattern, characteristic of one or more fault conditions, within the frequency spectrum; and determine one or more faults within the synchronous machine based on identifying the pattern.

The computer program may be stored on a non-transitory computer-readable medium.

The computer program may comprise instructions arranged to configure the data processing apparatus of the second aspect to perform one or more further steps of embodiments of the method of the first aspect disclosed herein.

A frequency-domain signal processing tool may be used to determine the frequency spectrum.

Some embodiments may be suitable for detecting faults in permanent magnet synchronous machines (PMSM). PMSMs may be used in various application areas such as e-aviation, drones, e-ship, e-automotive, and wind farms on large scale. PMSMs are prone to various types of faults such as inter-turn short circuit faults in the stator winding, static eccentricity fault, dynamic eccentricity, misalignment, and demagnetization. When used on PMSMs, a pattern may be extracted using one or more sensors, such as a search coil, mounted on the stator's backside or frame. A detected pattern may be a same pattern as disclosed in other embodiments herein (e.g. as for wound-field synchronous machines). In some PMSM embodiments, a number of sensors to detect misalignment may be one or more, e.g. up to eight sensors. A frequency-domain signal processing tool may be used to determine the frequency spectrum. The frequency spacing in the frequency spectrum may be similar to what is presented in the following pages, and the required data may be only limited to the frequency of the stator terminal and the number of rotor poles.

### BRIEF DESCRIPTION OF THE DRAWINGS

Details of certain non-limiting exemplary embodiments and optional features are disclosed in the following pages of description and the following drawings.

FIG. 1 shows Finite Element Modelling of three generators with power rating of 100 KVA (WFSG I), 22 MVA (WFSG II), and 400 MVA (WFSG III) and the location of the installed sensors on their back side.

FIG. 2A shows the approximate distribution of rotor MMF during healthy operation

FIG. 2B shows the approximate distribution of rotor MMF influenced by a demagnetizing component (b).

FIG. 2C shows the approximate distribution of rotor MMF with an ITSC fault.

FIG. 3 shows the frequency spectrum of a simulation of a 22 MVA (WFSG II) operating in open-circuit case under various degree of ITSC faults.

FIG. 4 shows the frequency spectrum of a simulation of a 22 MVA (WFSG II) operating in open-circuit case under various degree of DE faults.

FIG. 5 shows the frequency spectrum of a simulation of a 22 MVA (WFSG II) operating in open-circuit case under mixed faults of ITSC and SE faults.

FIG. 6 shows the frequency spectrum of a simulation of a 22 MVA (WFSG II) operating in open-circuit case under mixed faults of DE and SE faults.

FIG. 7 shows a frequency spectrum of a simulation of a 22 MVA (WFSG II) operating in open-circuit case under mixed faults of ITSC and DE faults.

FIG. 8A shows introduced patterns for detection of ITSC in WFSGs.

FIG. 8B shows introduced patterns for detection of DE in WFSGs.

FIG. 8C shows introduced patterns for detection of mixed faults of ITSC and DE in WFSGs.

FIG. 9 shows a flowchart of proposed patterns for mixed fault detection based on proposed algorithm in FIGS. 8A-C.

FIG. 10 shows a frequency spectrum of a simulation of a 400 MVA (WFSG III) operating in open-circuit case in a healthy case and under ITSC faults.

FIG. 11 shows a frequency spectrum of a simulation of a 100 kVA (WFSG I) operating in open-circuit case in a healthy case and under various degree of ITSC faults.

FIG. 12 is a set of photographs arranged schematically to show the experimental setup of a 100 KVA WFSG-I including a 100 kVA converter, 100 KW induction motor, gearbox, rotor field excitation, generator, power grid, and oscilloscope.

FIG. 13 shows a frequency spectrum from experimental results of a 100 KVA (WFSG I) operating in open-circuit case under various degree of ITSC faults.

FIG. 14A shows a frequency spectrum from experimental results of a 100 KVA (WFSG I) operating under on-load conditions, resistive load (30 KW)

FIG. 14B shows a frequency spectrum from experimental results of a 100 kVA (WFSG I) operating under resistive-inductive load (60 kW+24 KVAR).

FIG. 15 is a photomontage showing the location of the installed search coil on the stator backside of WFSG II with a power rating of 22 MVA.

FIG. 16A shows a frequency spectrum of a field test of a 22 MVA (WFSG II) operating in open-circuit.

FIG. 16B shows a frequency spectrum of a field test of a 22 MVA (WFSG II) operating under on-load case (17 MW).

### DETAILED DESCRIPTION OF EMBODIMENTS

Providing secure electricity depends on the reliable operation of the synchronous generators in power plants. Inter-turn short circuit (ITSC) and dynamic eccentricity (DE) faults are among the most prevalent fault types in wound field synchronous generators (WFSGs). Among the various signals used to detect faults such as current, voltage, and vibration, the stray magnetic field provides higher sensitivity for early-stage ITSC and DE detection. The introduced detection methods rely on comparison of various signals frequency spectrum's from fault and healthy generators. However, obtaining a frequency spectrum of a healthy synchronous generator that has been operating for decades in a power plant is almost impossible. A unique pattern is introduced using fast Fourier transform that can be implemented on a low-end microcontroller and ideal for IoT solutions. The efficacy of the proposed pattern is examined by finite element modeling and validated on a 100 KVA WFSG setup in the laboratory and field test in power plant with a power rating of 22 MVA.

Wound field synchronous machines are primarily used as generators in power plants. The type of wound field synchronous generator (WFSG) that operates in hydropower plants is a synchronous generator with a salient rotor pole due to the low speed of the prime mover [1]. The power rating of the WFSG in hydropower plants varies from a few megawatts to hundreds of megawatts due to different winding configurations although the topologies look similar. The reason for the power rating variation is due to the location of the installed WFSG and the dam capacity and head.

Two kinds of mechanical faults are prevalent in the WFSGs of hydropower plants located inside mountains: static eccentricity (SE) and dynamic eccentricity (DE) faults [2]. Mainly, the rock mass movement is the reason of SE fault in WFSGs. This is because the majority of the generator is housed in the concrete walls in the generator pit, which are in direct contact with the mountainous rock mass. On the other hand, the main reasons for DE faults in the WFSGs of hydropower plants include mechanical defects in the bearings due to aging, shaft current, and the force from rock mass movement. Eccentricity faults can have severe negative effects on the system operation. The vibration level can become higher due to SE or DE faults, trigger system protection and shut WFSG down to avoid further damage. In some cases, the power plant operators limit the operating power of the WFSG to reduce the vibration level which results in the reduced power generation.

Inter-turn short circuit (ITSC) fault in the rotor field winding is also among the prevalent fault types in WFSGs. Insulation degradation due to aging, thermal stress, and the unbalanced magnetic field are the main root causes of the ITSC in the rotor field windings. Although the WFSG can operate for a long time when the number of shorted turns are low, the local temperature rise due to ITSC fault can deteriorate the healthy turns and yield sudden rotor winding failure. Both ITSC and DE faults in WFSGs cause variations in the stator and rotor inductances and influence the current and voltage waveforms. Stator current is commonly used for DE fault detection of WFSGs [3]-[8]. The amplitude of fault related harmonics does not increase in the stator current when WFSGs operate under DE fault until it becomes severe [3], [6]. Eccentricity fault detection using the stator current is only possible during on-load operation of the WFSG; therefore, fault detection during open-circuit operation is impossible. Also, the introduced harmonics for DE fault are the same as harmonics in the power grid: namely 7th, 11th, 13th, 17th, and 19th. Therefore, there is a high possibility of false detection in the grid-tied operation of the WFSG. The current analysis detection method is not limited to the stator terminal current; the split phase current in the WFSG with parallel winding can be used for DE fault detection. However, the split phase current is caused due to the circulating current in the parallel winding when a severe eccentricity fault occurs [6]. Indicating that the split phase current is not a proper signal for the early stage eccentricity fault detection. The eccentricity fault induce harmonic components at twice the operating frequency in the rotor field current. However, the induced harmonics in the rotor current are not sensitive to the eccentricity fault with the low severity [6].

The stator terminal voltage is used for ITSC and DE fault detection both in the open-circuit and grid-tied operation of the WFSG [9]-[11]. The sub-harmonics and inter-harmonics variation in stator terminal voltage due to ITSC and DE faults are higher compared to the ones in stator current. However, the non-linear load can influence the fault-related harmonics in the stator terminal voltage, and hence affect the fault diagnosis performance. For instance, detecting an ITSC fault below 5% of total turns or a 10% DE fault using stator terminal voltage is impractical.

The air gap and the stray magnetic field (SMF) based on studies demonstrate a promising result for sensitive ITSC and DE fault detection of WFSGs [12]-[16]. The ITSC and DE faults yield in the asymmetric magnetic field in the air gap. The air gap magnetic field can be measured using a search coil wound around the stator tooth or a hall-effect sensor mounted on the stator tooth. The SMF, which is the mirror of the air gap magnetic field, can also provide informative data for the early stage detection of ITSC and DE faults [2], [8], [17]. Although both air gap and SMF are highly sensitive to early-stage DE and ITSC faults detection, the proposed detection methods using fast Fourier transform (FFT) and time-frequency (T-F) domain signal processing tools have the following difficulties:
1) A detection method using frequency spectrum analysis and compare the faulty and healthy side band components is not practical since it is impossible to obtain healthy WFSG data for very old ones operating for decades [8].
2) In many studies [18], [19], a threshold is defined and some harmonic components such as side bands around the main frequency component are selected as fault indicator. However, power rating and the specification of the WFSG can change the threshold level, indicating that the proposed method is unreliable.
3) Although DE and ITSC detection based on T-F domain signal processing method provides a unique pattern and does not need a priori knowledge of the WFSGs [8], [20], it requires computationally intensive algorithms and requires costly data processing hardware.

It can be concluded that a detection method that can improve the shortcomings of the existing methods is required: a method that can identify ITSC and DE faults in the early stage while the WFSG operates in the open-circuit or grid-tied conditions. The method must be able to determine the fault type with a high level of accuracy and it must be implemented using simple inexpensive processing hardware. In this work, we propose applying FFT to SMF measured on the stator backside of the WFSG. Although the application of FFT to the SMF for ITSC and DE fault detection have been proposed in [18], by comparing a faulty frequency spectrum with the healthy ones, at least some of the embodiments described herein have the following novel features:
1) Unique patterns for ITSC and DE faults detection are proposed using the SMF signal. The detection method based on the introduced patterns eliminates the need for the healthy frequency spectrum of the WFSG.
2) The introduced patterns are identical regardless of power rating and topology of the WFSGs
3) Since the coexistence of two faults such as ITSC and DE in power plants is unavoidable, a unique pattern is introduced to distinguish the mixed fault.

An analytical method based on the wave and permeance method is developed and two frequency signatures are introduced to pinpoint the DE and ITSC fault-related components in the frequency spectrum. Finite element modeling (FEM) of three WFSGs with the power rating of 100 KVA, 22 MVA, and 400 MVA are simulated with various degrees of DE and ITSC faults. An extensive experimental test on the 100 KVA WFSG test bench is carried out to validate the proposed method. A field test is performed on a 22 MVA WFSG in a power plant during open-circuit and grid-tied operation to validate the proposed method in reality.

### Finite Element Modelling (FEM)

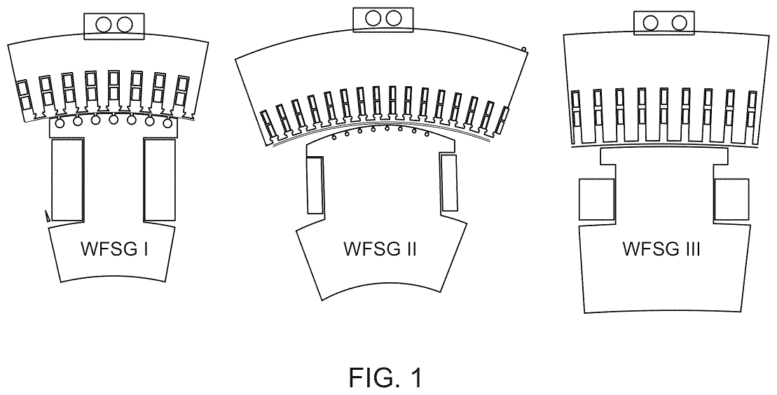

FEM is used to simulate the impact of DE and ITSC faults on the SMF of three WFSGs. FIG. 1 exhibits the 2-D FEM of the WFSGs. A detailed specification and nameplate data of three WFSGs are shown in Table. I. The strength of the magnetic field begins flagging the further it gets from the stator core, indicating that the amplitude of the SMF on the stator backside is in the order of microtesla. A precise SMF can be achieved in FEM by considering the detailed specification of the geometry, winding layout, eddy current in the damper bars, and saturation effect in the lamination sheets. The eddy current effect must be considered in the synchronous generator with the fractional winding layout, since the sub-harmonics generated due to fractional winding create a circulating current in the damper bar circuit even during steady-state operation.

The metallic housing of the electric machine has a significant impact on the SMF whereas it can attenuate and distort the SMF signal. However, the housing of WFSGs in the hydropower plants is the wall in the generator pit. Therefore, there is direct access to the stator core, and modelling of the generator housing is disregarded in FEM.

The SMF can be measured by using a search coil with the desired number of turns on the stator core back side, as shown in red circles in FIG. 1. Based on the location of the search coil in the 2-D FEM, the type of measured SMF is the combination of radial and axial magnetic fields. Measuring a pure radial or axial SMF requires 3-D FEM. However, the search coil position as depicted in FIG. 1 is preferred due to its close contact with the stator core. The amplitude and pattern of the induced sensor voltage in the simulation are influenced by:
1) The amplitude of the induced sensor voltage depends on the number of turns in the search coil, the geometry and the distance of the coils from the stator core.
2) There must be a diminutive air gap between the coils and the stator core in the simulation. Because the material properties of the core and the search coil are not the same, and this can result in an incorrect induced voltage waveform.

TABLE I
SPECIFICATION AND NAMEPLATE DATA OF THREE GENERATORS WITH POWER RATING
OF 100 kV A (WFSG I), 22 MV A (WFSG II), AND 400 MV A (WFSG III)

| Quantity | WFSG I | WFSG II | WFSG III | Quantity | WFSG I | WFSG II | WFSG III |
|---|---|---|---|---|---|---|---|
| Stator outer diameter (m) | 0.78 | 2.640 | 11.27 | Number of poles | 14 | 8 | 60 |
| Stator inner diameter (m) | 0.65 | 2.040 | 10.62 | Terminal voltage (kV) | 0.4 | 7.7 | 56 |
| Length of stack | 0.208 | 1.22 | 1.62 | Frequency | 50 | 50 | 60 |
| No. of damper bars/pole | 7 | 8 | 7 | Terminal current (A) | 144.3 | 1650 | 7100 |
| No. of stator turns | 8 | 1 | 3 | No. of slots | 114 | 126 | 504 |
| Nominal speed (rpm) | 428 | 750 | 120 | Power Factor | 0.90 | 0.90 | 0.90 |

The number of search coils required to be installed on the WFSG depends on the investigated fault types. One sensor is adequate for ITSC fault detection since the SMF does not vary along the axial axis of the WFSG. The length of the air gap varies both in time and location in the case of radial DE fault; therefore, one sensor is adequate for DE detection.

### Inter-Turn Short Circuit Fault

The SMF on the stator backside is the attenuated form of the air gap magnetic field, indicating that their frequency contents are almost identical [2]. Both ITSC and DE faults distort the air gap magnetic field and can be analyzed using a wave and permeance method. The air gap magnetic field is the combination of the stator and rotor magnetic fields. Therefore, the air gap permeance needs to be formulated by the inverse of the air gap length and then multiplied to the magneto-motive force (MMF) generated by the rotor and the stator winding currents to obtain the radial air gap magnetic field [10], [19]. The air gap function of a WFSG with slotted stator and saturation effects can be written as [10]:

$$g ( ϕ , t ) = {g}_{sat} ( ϕ , t ) = \frac{{C}_{c} ( {k}_{m} - {k}_{e} cos ( 2 {ω}_{s} - 2 p ϕ ) )}{{α}_{1} + {α}_{2} cos ( 2 p ( \frac{{ω}_{s} t}{p} - ϕ ) )} \qquad ( 1 )$$

where C_{c} is the carter coefficient, p is the number of pole pairs, φ is an angle along the inner surface of the stator, ωₛ is the angular velocity, kₘ, and kₑ are the saturation coefficients, and α₁ and α₂ are coefficients to consider rotor pole saliency [10]. The air gap magnetic field is consisted of air gap permeance multiplied with MMF. The air gap permeance is the inverse of the air gap function that can be expanded as:

$$Λ = {\sum }_{κ = 0}^{∞} {Λ}^{κ} cos ( ( 2 κ + 2 ) {ω}_{s} t - 2 p ( κ \pm 1 ) ϕ ) . \qquad ( 2 )$$

where ∧^{κ} is the amplitude of the permeance wave, including saturation and slotting effects corresponding to the value of summation index κ.

The stator and rotor windings generate MMF in the air gap, where rotor field winding only contributes to air gap MMF during no-load operation. The DC current flowing in the rotating poles causes MMF waves to travel at synchronous speed seen from the stator reference frame. Thus, the current density produced by a healthy field winding can be written as:

$${j}^{r} ( ϕ , t ) = {J}^{r} sin ( {ω}_{s} t - p ϕ ) \qquad ( 3 )$$

where Jᵣ is the maximum value of the rotor current density.

The rotor MMF for a healthy WFSG can be calculated by Ampere's law as follows:

$${ℱ}_{h}^{r} ( ϕ , t ) = ∮ {j}^{r} ( ϕ , t ) d ϕ = \frac{{J}^{r}}{p} cos ( {ω}_{s} t - p ϕ ) \qquad ( 4 )$$

Although the air gap permeance for the WFSG under ITSC is similar to a healthy operation, MMF generated by the faulty rotor pole is decreased due to the reduction in the number of rotor winding turns. The resulting rotor MMF can be represented by a superposition of the healthy rotor MMF and a MMF due to ITSC that can act as a demagnetizing component.

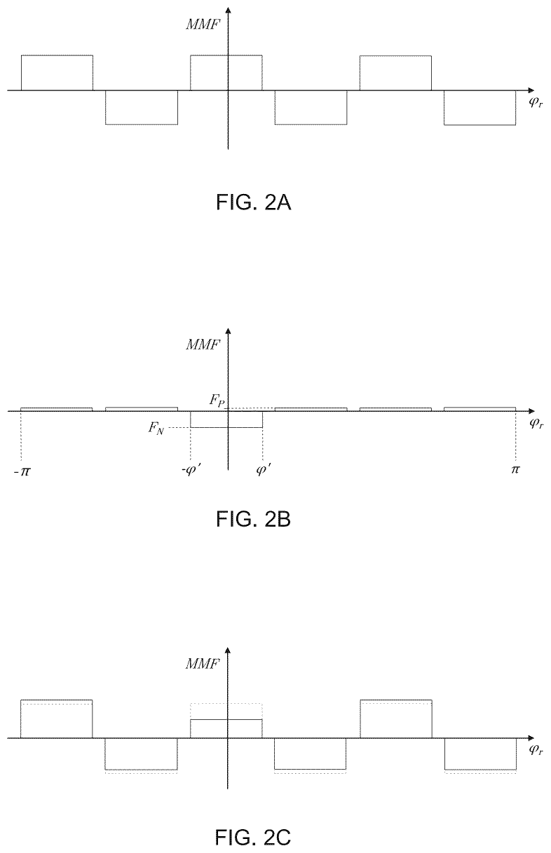

FIG. 2A illustrates a simplified representation of the MMF produced by a rotor of the healthy WFSG. The rotor MMF distribution is spatial with respect to the rotor, denoted by φᵣ, and can be approximated as a sinusoidal function. FIG. 2B depicts the fictitious demagnetizing component caused by the ITSC fault. The amplitude of the demagnetizing component (FN) depends on the number of shorted turns in the rotor pole. The ITSC fault influence not only the faulty pole but also the neighbouring poles. In FIGS. 2A-C, it is assumed that the combined area of the MMF above the y axis is equal to the demagnetizing MMF component. FIG. 2C shows the resultant rotor MMF when MMF of the healthy rotor pole is added to the demagnetizing component. Red lines represent a reduction of the MMF while green lines represent increased MMF in some of the neighbouring poles. Mathematically, the distribution of the faulty MMF,

$${ℱ}_{sc}^{r} ,$$

can be written in terms of the healthy MMF distribution, [symbol] ₕ, and the MMF distribution of the fault pole, [symbol] _{f}, according to (5).

$${ℱ}_{sc}^{r} ( ϕ , t ) = {ℱ}_{h}^{r} ( ϕ , t ) + {ℱ}_{f}^{r} ( {ϕ}_{r} ) {ℱ}_{f}^{r} ( ϕ , t ) \qquad ( 5 )$$

can be expressed in terms of Fourier series as follows:

$${ℱ}_{f}^{r} ( {ϕ}_{r} ) = {a}_{0} + {\sum }_{n = 1}^{∞} {a}_{n} cos ( n {ϕ}_{r} ) + {b}_{n} sin ( n {ϕ}_{r} ) \qquad ( 6 )$$

where the Fourier coefficients of a0 and bn are zero due to the symmetry of the MMF function with respect to the y axis. Therefore the MMF distribution of the demagnetizing component can be written as:

$${ℱ}_{f}^{r} ( {ϕ}_{r} ) = {\sum }_{n = 1}^{∞} \frac{2 ( {F}_{N} - {F}_{P} )}{n π} sin ( n {ϕ}^{′} ) cos ( n {ϕ}_{r} ) . \qquad ( 7 )$$

From a rotor point of view, the location of this component is determined by the reference angle, φᵣ. However, seen from the stator,

$${ℱ}_{f}^{r}$$

rotates in the air-gap with velocity

$${ω}_{r} = \frac{{ω}_{s}}{p} .$$

Thus, its location depends on both the stator reference angle, φ, and the time, t. Consequently, with (7) referred to the stator reference frame and with simplified notation for the amplitude of each term of the Fourier series, the total MMF of a rotor considering ITSC fault can be expressed as:

$${ℱ}_{sc}^{r} ( ϕ , t ) = \frac{{J}^{r}}{p} cos ( {ω}_{s} t - p ϕ ) + {\sum }_{n = 1}^{∞} {F}_{f , n} cos ( \frac{n}{p} {ω}_{s} t - n ϕ ) \qquad ( 8 )$$

The air gap magnetic field of the WFSG while operating in the open circuit condition can be calculated by having rotor MMF and the air gap permeance. Thus, the air gap magnetic field under ITSC fault is:

$${b}_{sc}^{r} ( ϕ , t ) = {\sum }_{κ = 0}^{∞} {\sum }_{υ = 0}^{∞} {B}_{sc}^{κ , υ , τ} cos ( ( 2 κ \pm \frac{υ}{p} ) {ω}_{s} t - ( 2 p κ \pm υ ) ϕ ) \qquad ( 9 )$$

where

$${B}_{sc}^{κ , υ , τ}$$

denotes the amplitude of the air gap magnetic field under the ITSC fault during open circuit operation of the WFSG. The impact of ITSC fault on the frequency components of the SMF can be traced as follows:

$${f}_{sc} = ( 2 κ \pm \frac{υ}{p} ) {f}_{s} \qquad ( 10 )$$

where fₛ is the stator terminal frequency, p is the number of rotor pole pairs, and κ and v are any integers.

### Eccentricity Fault

Eccentricity is modelled by including the variable air gap length that occurs during eccentric operation of the WFSG into the air gap function as follows:

$${g}_{ec} ( ϕ , t ) = g ( ϕ , t ) ( 1 - {δ}_{de} cos ( ψ ) ) \qquad ( 11 )$$

where δ_{de} is the degree of DE and ψ is the eccentricity angle equates to

$$\frac{{ω}_{s} t}{p} - ϕ .$$

Conclusively, the air gap function considering eccentricity fault is:

$${g}_{ec} ( ϕ , t ) = \frac{{C}_{c} ( {k}_{m} - {k}_{e} cos ( 2 {ω}_{s} - 2 p ϕ ) ) ( 1 - {δ}_{ec} cos ( ψ ) )}{{α}_{1} + {α}_{2} cos ( 2 p ( \frac{{ω}_{s} t}{p} - ϕ ) )} \qquad ( 12 )$$

The air gap permeance, which is the air gap length inverse, is required to calculate the air gap magnetic field. The DE fault imposes a cosine term that varies with both time and position. The air gap permeance of WFSG under DE fault, ∧_{de}, can be formulated as:

$${Λ}_{de} = {\sum }_{κ = 0}^{∞} {\sum }_{υ = 0}^{∞} {Λ}_{de}^{κ , υ} cos ( ( 2 κ \pm \frac{υ}{p} ) {ω}_{s} t - ( 2 p ( κ \pm 1 ) \pm υ ) ϕ ) \qquad ( 13 )$$

where

$${Λ}_{de}^{κ , υ}$$

is the amplitude of the permeance wave, including saturation and slotting effects corresponding to the value of summation index κ and v.

The MMF in the air gap during the open circuit operation of the WFSG contains only rotor MMF according to (4). The air gap magnetic field of WFSG during open circuit operation under DE fault is as follows:

$${b}_{de}^{r} ( ϕ , t ) = {\sum }_{κ = 0}^{∞} {\sum }_{υ = 0}^{∞} {B}_{de}^{κ , υ} cos ( ( 2 κ \pm \frac{υ}{p} ) {ω}_{s} t - ( 2 p ( κ \pm 1 ) \pm υ ) ϕ ) \qquad ( 14 )$$

where

$${B}_{de}^{κ , υ}$$

denotes the amplitude of the air gap magnetic field under the DE fault. The occurrence of the DE fault results in the amplitude variation of the frequency components in the SMF that can be traced as follows:

$${f}_{de} = ( 2 κ \pm \frac{υ}{p} ) {f}_{s} \qquad ( 15 )$$

### Fault Detection and Classification

T-F domain-based signal processing methods are able to detect and recognize DE and ITSC faults in WFSG [8], [20]-[22]. However, there exist two main challenges in using T-F based signal processing methods:
1) The industry requires a simple approach that can be implemented using a low-end microcontroller. However, the detection method based on T-F analysis needs costly data processing hardware.
2) The T-F plot requires expert knowledge or a complicated algorithm for the pattern analysis. FFT pattern analysis can be performed using inexpensive data processing hardware such as FPGA.

Fault detection of WFSG based on FFT analysis relies on the variation analysis of the frequency components [18], [19]. However, a comparison between (10) and (15) shows that both ITSC and DE faults give rise to the same frequency components in the SMF frequency spectrum. Although the frequency spectrum is able to demonstrate the faulty operation of the WFSGs, fault type detection is not possible. Therefore, the introduction of a unique pattern for each fault type can be an optimal solution.

### Pattern Recognition of ITSC and DE Faults

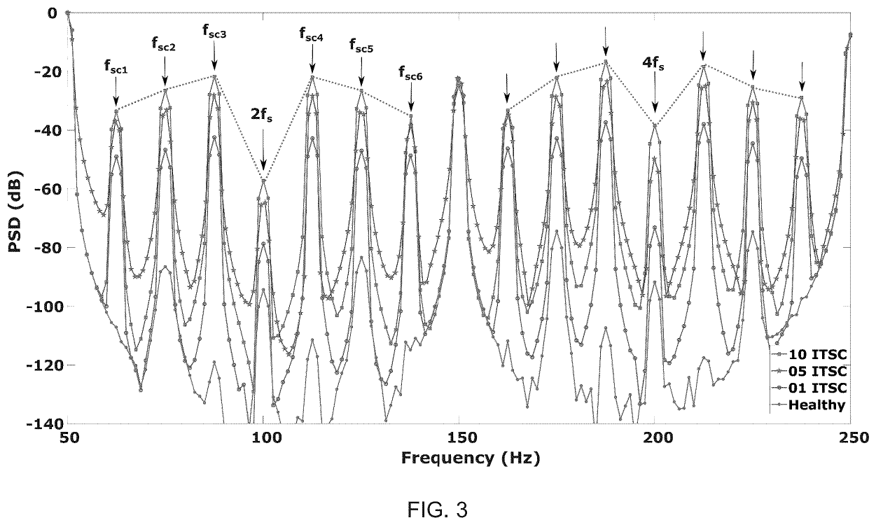

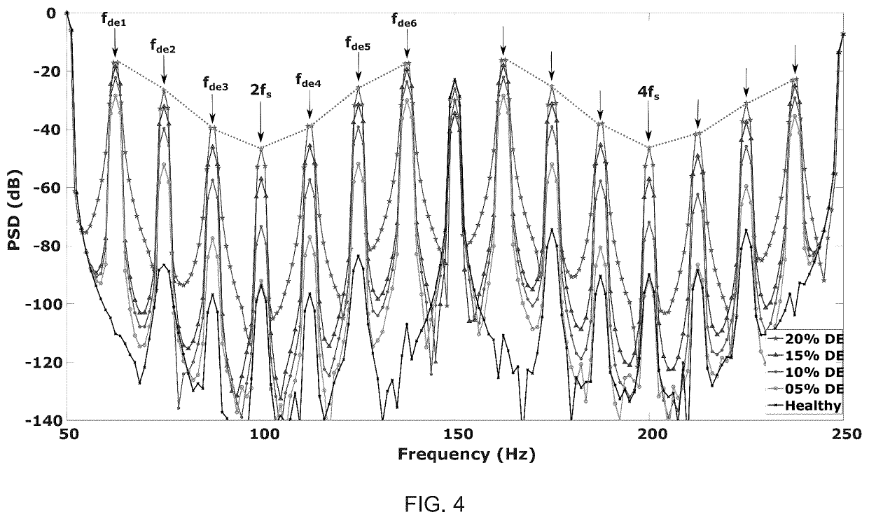

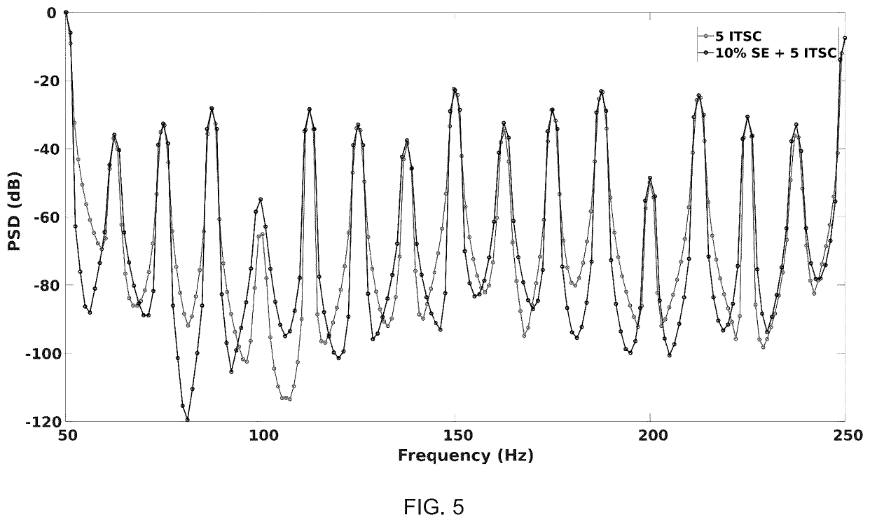

SMF is a highly sensitive signal to ITSC and DE fault where fault with low-severity can increase the amplitude of the frequency components as shown in FIGS. 3 and 4. As shown in Table II and Table III, the impact of 1 ITSC and 5% DE faults in the frequency spectrum of the 22 MVA WFSG operating in open-circuit condition result in the faulty components augmentation based on (10) and (15). FIG. 3 indicates a unique pattern where the amplitude of the faulty frequency components (f_{sc}) between fₛ and 2fₛ are increased. Moreover, the ITSC pattern has symmetry around the 2fₛ. The same pattern is repeated between 3fₛ and 5fₛ. Increasing the number of faulty turns do not change the frequency pattern. FIG. 3 shows the impact of 1, 5, and 10 shorted turns on the frequency spectrum of the SMF.

TABLE II
FAULTY HARMONICS VARIATION IN DECIBEL
UNDER ITSC FAULT IN A 22 MVA WFSG
OPERATING IN NO-LOAD CONDITION

| Freq. (Hz) | | 62.5 | 75 | 87.5 | 100 | 112.5 | 124.3 | 137.6 |
|---|---|---|---|---|---|---|---|---|
| H | | −105 | −86 | −119 | −94 | −111 | −83 | −111 |
| 1 | ITSC | −49 | −46 | −42 | −78 | −43 | −47 | −48 |
| 5 | ITSC | −37 | −33 | −28 | −64 | −28 | −34 | −41 |
| 10 | ITSC | −33 | −26 | −22 | −57 | −22 | −26 | −38 |

TABLE III
FAULTY HARMONICS VARIATION IN DECIBEL
UNDER DE FAULT IN A 22 MVA WFSG
OPERATING IN NO-LOAD CONDITION

| Freq. (Hz) | | 62.5 | 75 | 87.5 | 100 | 112.5 | 124.3 | 137.6 |
|---|---|---|---|---|---|---|---|---|
| H | | −105 | −86 | −119 | −94 | −111 | −83 | −111 |
| 5% | DE | −28 | −52 | −77 | −92 | −77 | −51 | −30 |
| 10% | DE | −22 | −39 | −57 | −73 | −57 | −39 | −23 |
| 15% | DE | −18 | −32 | −46 | −57 | −45 | −31 | −19 |
| 20% | DE | −17 | −26 | −39 | −46 | −38 | −25 | −17 |

Although the frequency spectrum of a healthy WFSG as shown in FIG. 4 does not follow a uniform pattern, a low severity DE fault, 5%, can introduce a distinct pattern. The amplitude of the frequency components selected by (15) indicates a significant increment by having only 5% DE fault. The amplitude of faulty harmonics are increased by increasing the severity to 10%, 15%, and 20% DE fault as shown in Table III. The amplitude of f_{de} components between fₛ and 2fₛ are decreased while the amplitude of frequency components between 2fₛ and 3fₛ are increased. The introduced DE pattern is symmetrical between 3fₛ and 5fₛ. A comparison between FIGS. 3 and 4 indicate that each fault gives rise to a unique pattern in the frequency spectrum of the SMF.

### Mixed Fault Impact on Pattern Recognition

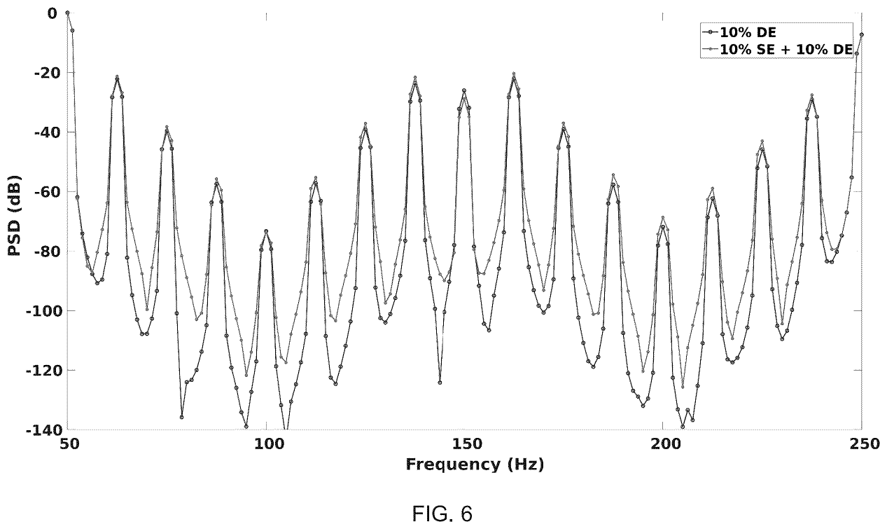

According to IEEE and IEC standards, up to 10% eccentricity fault in a brand new electric machine is allowed [10]. Indicating that there exists at least one fault during the operation of electric machines. The impact of 10% SE fault on a 22 MVA WFSG while 5 out of 58 turns in one of the rotor poles are short-circuited is shown in 5. SE fault does not change the amplitude and pattern of the frequency spectrum of the SMF while WFSG experiences ITSC fault. The impact of 10% SE fault on WFSG with 10% DE fault is shown in FIG. 6. SE fault change neither the amplitude nor the pattern of the frequency spectrum. Conclusively, the SE fault only changes the amplitude of the SMF while the frequency components are identical to healthy case [2].

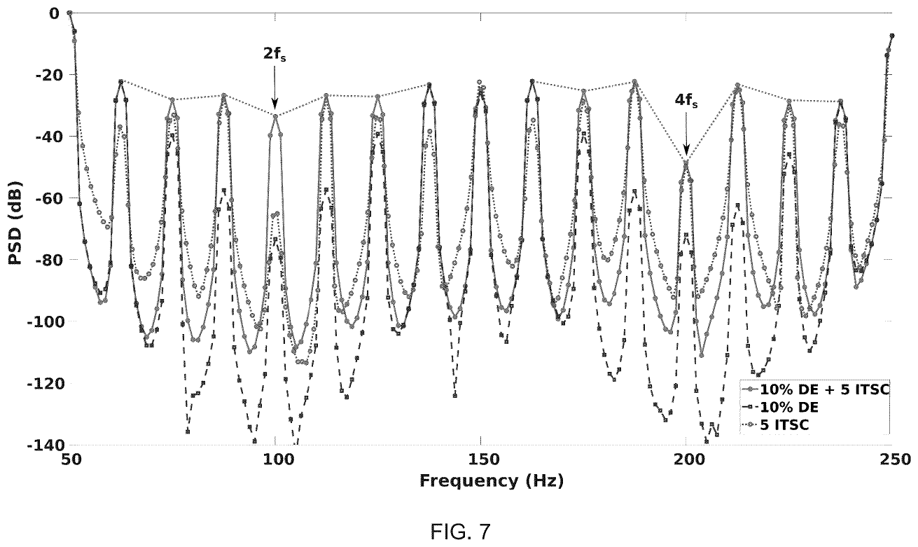

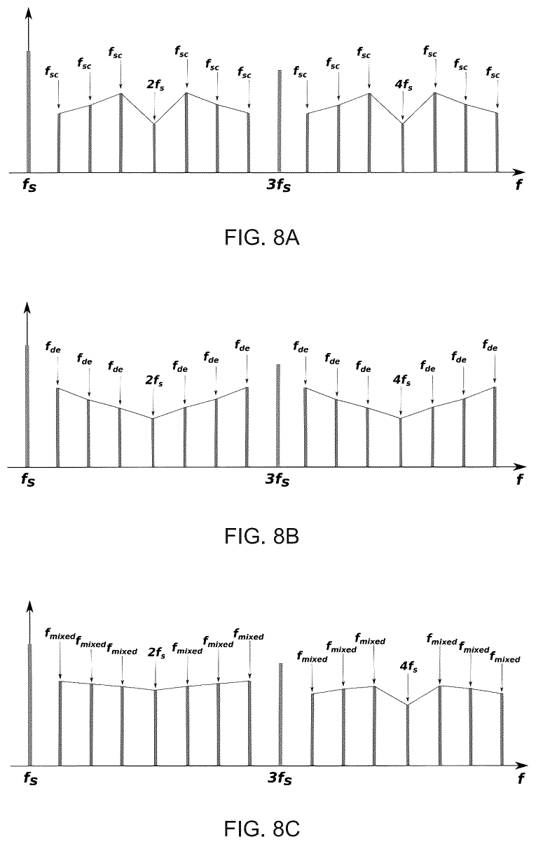

Co-existence of ITSC and DE faults can significantly influence both the amplitude and pattern of the frequency spectrum. FIG. 7 shows the frequency spectrum of a 22 MVA WFSG operating under 10% DE fault while 5 turns out of 58 turns of one of rotor pole winding is short-circuited. The co-existence of both ITSC and DE faults results in a significant amplification of the sideband harmonics in the frequency spectrum of the SMF. The amplitude of the sideband harmonics for the mixed fault (10% DE+5 ITSC) equates to the highest amplitude of each fault. However, the occurrence of mixed ITSC and DE faults give a rise to a unique pattern where the amplitude of frequency components between fₛ and 2fₛ are almost at the same level. The frequency pattern is symmetrical around the 2fₛ component. Moreover, the amplitude of the 2fₛ component compared with cases where WFSG operating under a single fault is increased markedly. FIGS. 8A-C show the introduced pattern for ITSC, DE, and mixed fault detection in WFSG where the frequency spacing for ITSC and DE faults follows the presented equations in (10) and (15).

### Detection Algorithm

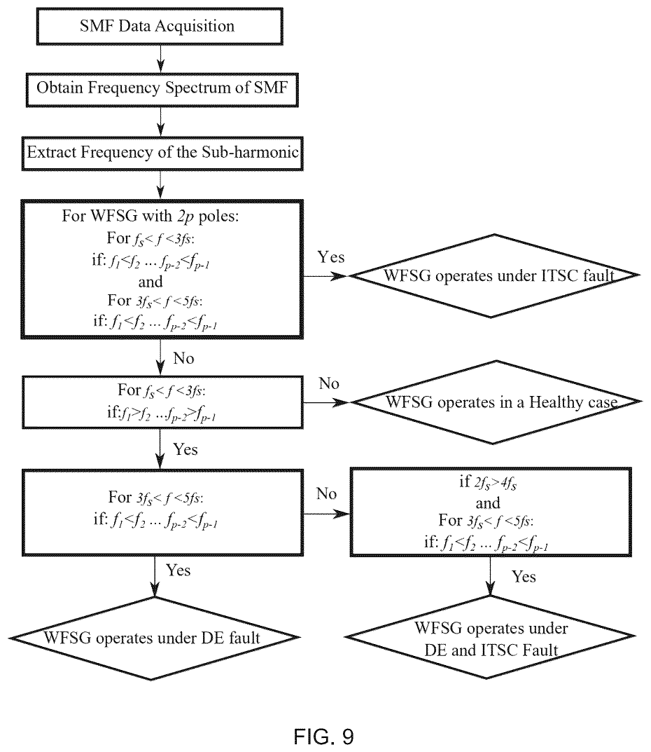

FIG. 9 shows the proposed detection algorithm. The input to the algorithm is limited to the main frequency of the machines fₛ, the number of rotor poles 2p, and the measured SMF. The subharmonics f can be determined based on (10) and only need the number of rotor poles and the frequency of the stator terminal. The first part of the algorithm analyses the frequency spectrum of the measured induced sensor voltage to detect the ITSC fault. Since the frequency components follow the same patterns around 2fₛ and 4fₛ, only frequency components between fₛ and fₛ, and 3fₛ and 4fₛ need to be checked. If the amplitude of the frequency components in the FFT spectrum follows the introduced pattern in FIG. 8, then the algorithm stops and shows that the WFSG has the ITSC fault. If any of the two defined if conditions are not satisfied in this step, the algorithm checks if frequency components between fₛ and 3fₛ have an increasing trend. If the condition is not met, the WFSG operates in a healthy condition. However, if an increasing trend is observed, the algorithm checks the possibility of DE and mixed faults. If the amplitude of the frequency component between 3fₛ and 5fₛ has a declining trend, the algorithm stops and shows the DE fault alarm. Otherwise, the amplitude of the 2fₛ and 4fₛ needs to be checked. If the amplitude of the 2fₛ is greater than 4fₛ, the algorithm stops and shows the mixed DE and ITSC fault in the WFSG.

### Machine Topology Impact on Pattern Recognition

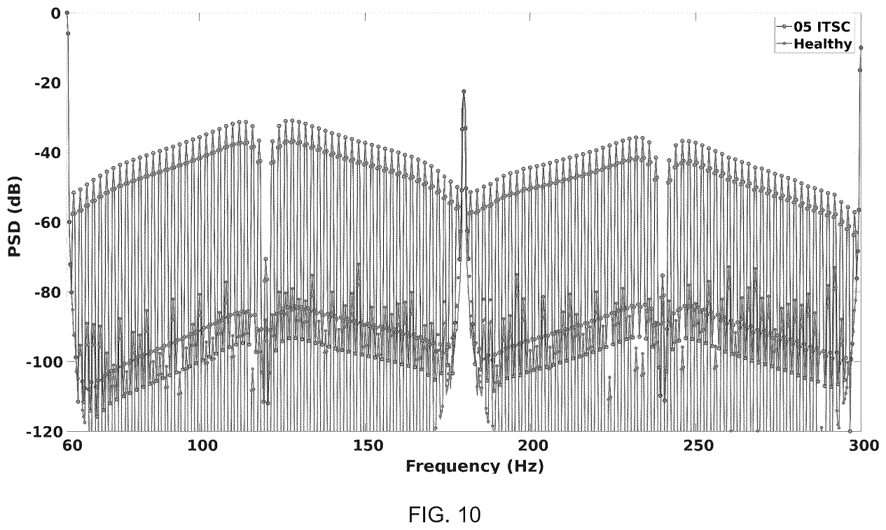

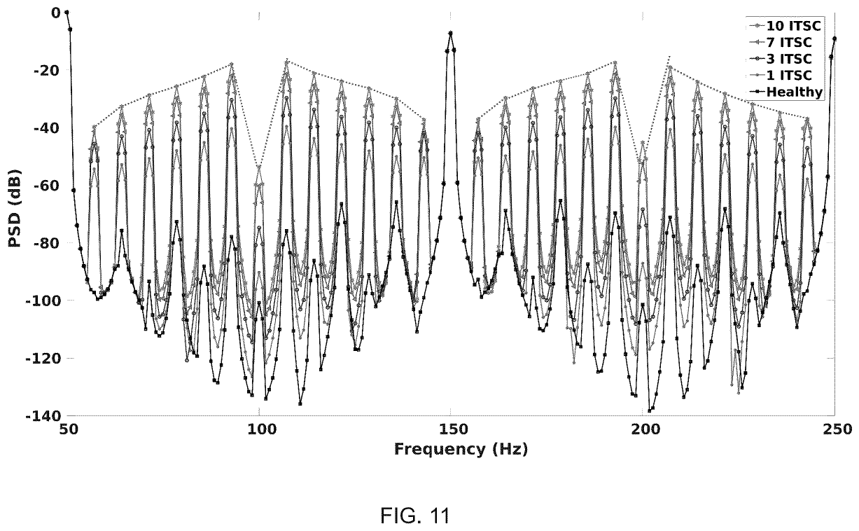

The electric machine topology and power rating have a significant impact on the amplitude of the SMF frequency spectrum. Indicating that defining a fault threshold level for side band harmonics is useless [8]. However, a comparison between the frequency spectrum of a 400 MVA WFSG (FIG. 10) and a 100 KVA WFSG (FIG. 11) with the introduced pattern in FIGS. 8A-C indicate that the proposed patterns for ITSC and DE faults are identical for WFSGs regardless of their power rating and topologies. Where in the case of ITSC fault, the frequency components between fₛ and 2fₛ are ascending and components between 2fₛ and 3fₛ are descending. Conversely, the DE fault impact on the frequency spectrum results in the descending pattern for frequency components between fₛ and 2fₛ and ascending pattern for frequency components between 2fₛ and 3fₛ. The only difference in the frequency spectrum of the 100 KVA and 400 MVA WFSGs is the number of side band components that depend on the number of rotor poles.

### Experimental Set-Up

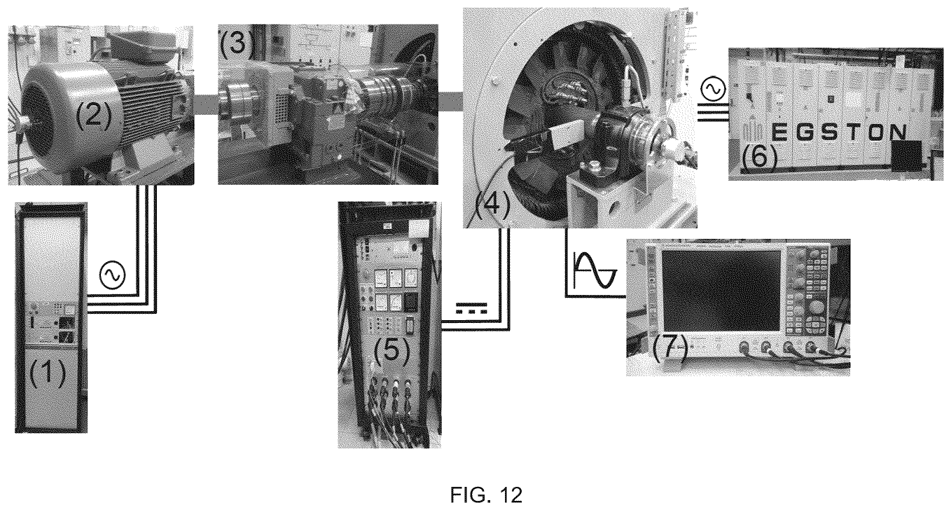

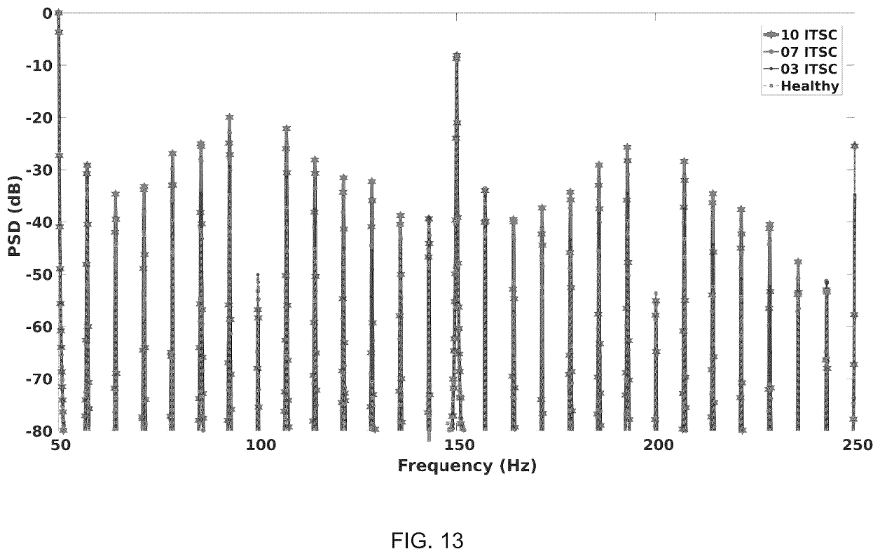

An experimental setup that consist of a 100 KVA WFSG operating at constant speed of 428 rpm is used to examine the feasibility of the proposed pattern for ITSC fault detection. FIG. 12 shows the constituent elements of the setup. The setup consists of a 100 KVA converter 1 that fed a 100 KVA induction motor 2. The induction motor 2 is connected to the WFSG using a gearbox 3 with a transfer rate of 10/3. The custom-made synchronous generator with 14 salient poles 4 with maximum power rating of 100 KVA is excited by a 20 KW programmable power supply 5. Ultimately, the terminal voltage of the WFSG is connected to the power grid 6. Sensor system consisted of a custom-made search coil and a 16-bit oscilloscope 7 (Rohde & Schwarz RTO2044) which the measured signal was stored at a 10 KHz sampling frequency. A custom-made search coil that includes a plastic reel with a size of 100×100×10 mm, 3000 turns of thin copper wire with a cross-section of 0.12 mm², and a coaxial cable that transfers the induced sensor voltage to the oscilloscope. The amplitude of the induced voltage in the search coil depends on the area covered by the search coil and the number of turns. The number of search coil turns must be sufficiently high to diminish the noise impact on the induced voltage by increasing the signal to noise ratio.

ITSC fault is applied to one of rotor pole of a 100 KVA WFSG by removing 3, 7, and 10 turns out of 35 turns. FIG. 12 shows the frequency spectrum of 100 KVA WFSG operating in the open-circuit condition for various degree of ITSC fault. The frequency of the harmonic components can be determined using (10) where the fₛ and p are 50 Hz and 7. Although the frequency components for the healthy case has a chaotic amplitude distribution, having 3 shorted turn in one of rotor poles give rise to the introduced pattern in FIG. 8.

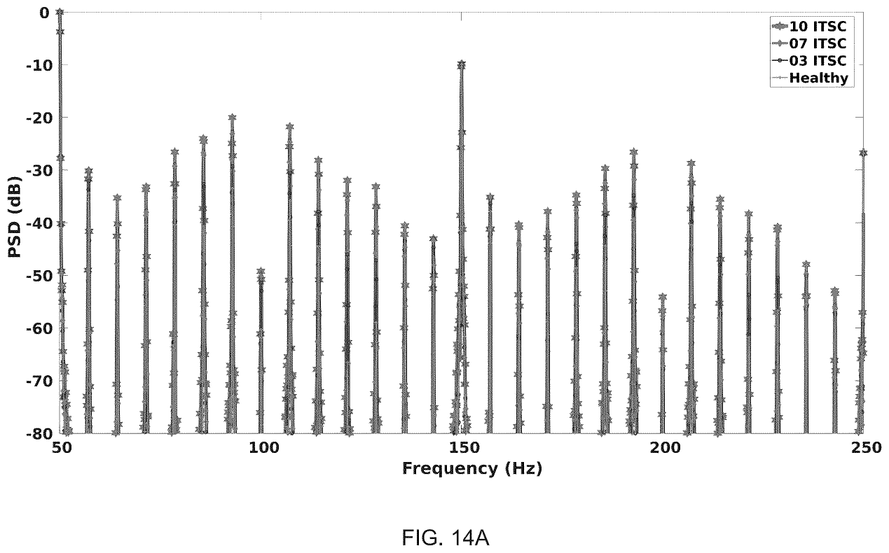

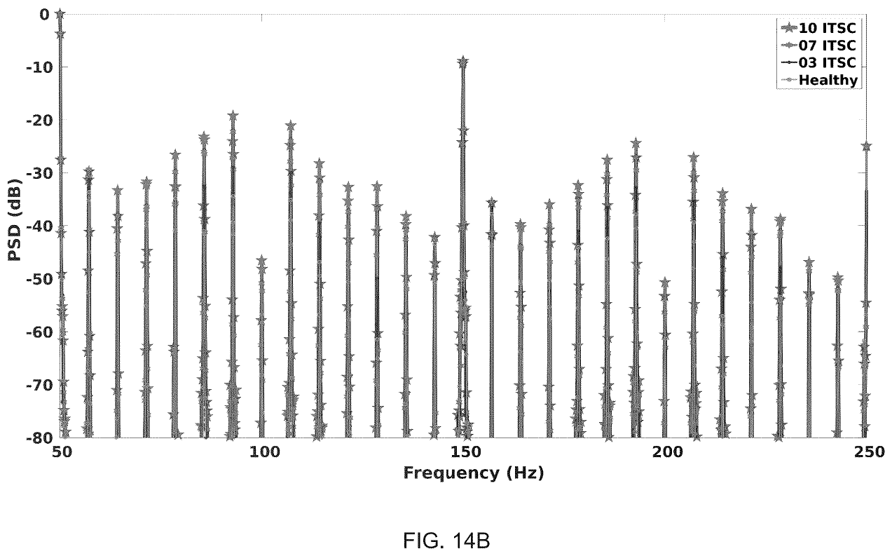

The load harmonics have a significant impact on the frequency components of voltage and current in the WFSG [10], [11]. But, the SMF is almost immune from the load harmonics' influence on the fault harmonic components. The impact of resistive (30 KW) and resistive-inductive (60 kW+24 kVAR) loads on the frequency spectrum of a 100 KVA WFSG during the healthy case and under the various degree of ITSC faults are shown in FIGS. 13A-B. The amplitude of the faulty frequency components for both resistive and resistive-inductive loads are similar to the frequency spectrum of the generator during open-circuit operation.

### Field Test

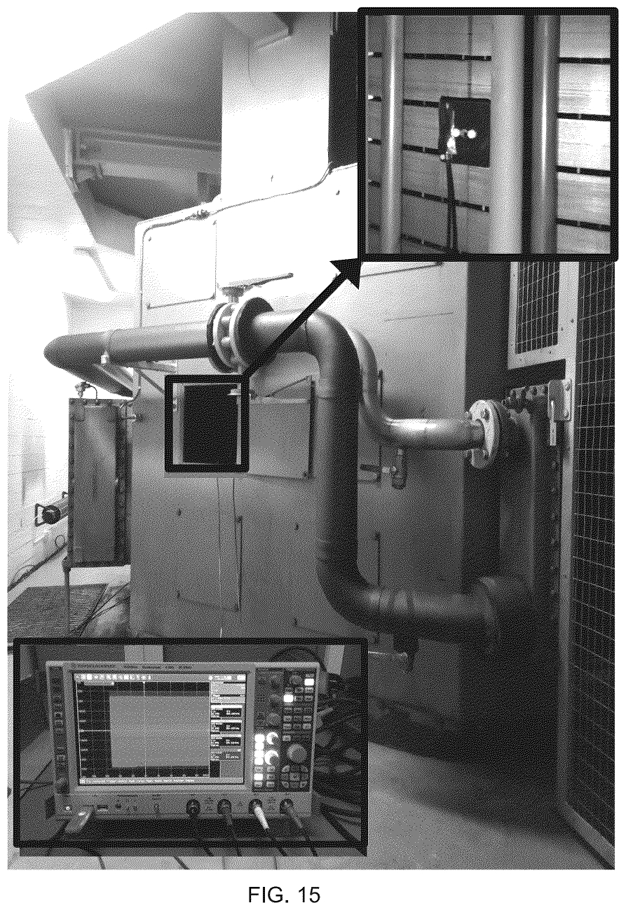

The vibration amplitude of the 22 MVA WFSG during open-circuit and grid-tied operations is intensified according to the periodic maintenance report of the hydropower plant. The measurement based on the application of SMF is planned to investigate the root cause of vibration. The required equipment for the field test is limited to the custom-made search coil and one oscilloscope. FIG. 15 shows the 22 MVA vertically mounted WFSG encapsulated by the metallic housing. However, there are several hatches around the housing that provides direct access to the stator backside. The search coil cross-section is sufficient to cover one lamination stack area. There are several verticals and horizontal pillars to support the stator core. Therefore, the search coil must be installed in the middle of the vertical and horizontal pillars to avoid the interference of the magnetic fields that pass through the supporting pillars.

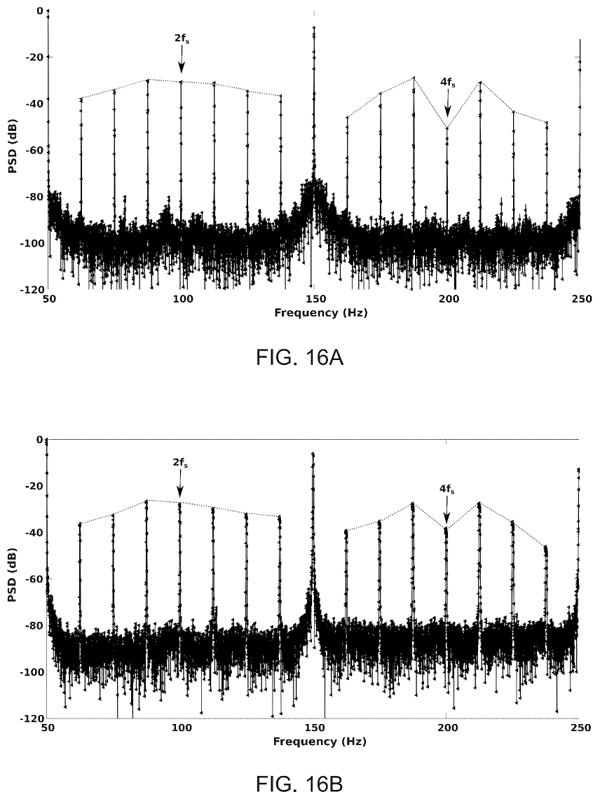

Several tests have been performed both in the open-circuit and grid-tied operation of the 22 MVA WFSG. The on-load operation of the WFSG is limited to 17 MVA to keep the vibration level below the protection relay's trip threshold. FIG. 16A shows the frequency spectrum of the open-circuit operation of the generator. The pattern of the harmonic components in the frequency spectrum between 3fₛ and 5fₛ is similar to the ITSC pattern in FIG. 8A. However, the frequency components limited between fₛ and 3fₛ follow the pattern of mixed ITSC and DE fault where the amplitude of the frequency components are very close to each other. In addition, the amplitude of the 2fₛ harmonic components is increased markedly which only happens in the case of mixed ITSC and DE faults. The frequency spectrum of the WFSG while connected to the grid is shown in FIG. 16B. The frequency spectrum during onload operation is similar to the open-circuit condition which indicates that the loading condition does not influence the frequency contents of the SMF.

### CONCLUSION

In this disclosure, unique patterns are proposed based on frequency spectrum analysis of SMF for ITSC, DE, and mixed faults detection in WFSGs. The SMF is used since it can provide a non-invasive measurement during WFSG operation in a power plant. FEM analysis of three WFSGs was performed to understand the ITSC and DE's impact on the measured SMF. It was shown that the power rating and topology of the WFSG do not influence the introduced patterns. Extensive tests have been performed on a 100 KVA WFSG to validate the introduced patterns. A faulty 22 MVA WFSG is selected to examine the proposed fault detection method. The application of the proposed method is able to detect and identify the mixed ITSC and DE fault both during open-circuit and gridtied operations of the 22 MVA generator. The following are the remarks on the introduced method for ITSC and DE faults detection of the WFSG:
1) The power rating and the topology of the WFSG have no impact on the introduced ITSC and DE patterns.
2) The introduced pattern is unique for each fault type that yields fault type detection of the WFSG.
3) WFSGs are vulnerable to mixed faults such as ITSC and DE, where the introduced pattern for mixed fault provides a precise fault type detection even for the co-existence of the two faults.
4) The proposed method can be implemented in the low-ended microcontroller and it is suitable for IoT solutions.
5) The proposed detection algorithm does not require a measurement of the brand new WFSG during commissioning or a predefined threshold value.
6) The proposed method can diagnose the ITSC and DE faults both during the open-circuit and grid-tied operation of the WFSG, indicating that the grid harmonics cannot distort the introduced pattern.

### REFERENCES

[1] T. A. Lipo, Analysis of synchronous machines. CRC press, 2017.
[2] H. Ehya, A. Nysveen, R. Nilssen, and Y. Liu, “Static and dynamic eccentricity fault diagnosis of large salient pole synchronous generators by means of external magnetic field,” IET Electric Power Applications, vol. 15, DOI https://doi.org/10.1049/elp2.12068, no. 7, pp. 890-902, 2021. [Online]. Available: https://ietresearch.onlinelibrary.wiley.com/doi/abs/10.1049/elp2.12068
[3] H. A. Toliyat and N. A. Al-Nuaim, “Simulation and detection of dynamic air-gap eccentricity in salient-pole synchronous machines,” IEEE Transactions on Industry Applications, vol. 35, no. 1, pp. 86-93, 1999.
[4] I. Tabatabaei, J. Faiz, H. Lesani, and M. T. Nabavi-Razavi, “Modeling and simulation of a salient-pole synchronous generator with dynamic eccentricity using modified winding function theory,” IEEE Transactions on Magnetics, vol. 40, no. 3, pp. 1550-1555, 2004.
[5] M. Babaei, J. Faiz, B. M. Ebrahimi, S. Amini, and J. Nazarzadeh, “A detailed analytical model of a salient-pole synchronous generator under dynamic eccentricity fault,” IEEE Transactions on Magnetics, vol. 47, no. 4, pp. 764-771, 2011.
[6] C. Bruzzese, “Diagnosis of eccentric rotor in synchronous machines by analysis of split-phase currents apart i: Theoretical analysis,” IEEE Transactions on Industrial Electronics, vol. 61, no. 8, pp. 4193-4205, 2014.
[7] K. N. Gyftakis, C. A. Platero, and S. Bernal, “Off-line detection of static eccentricity in salient-pole synchronous machines,” in 2018 XIII International Conference on Electrical Machines (ICEM), DOI 10.1109/ICELMACH.2018.8507042, pp. 1919-1924, 2018.
[8] H. Ehya, A. Nysveen, and J. A. Antonino-DAVIU, “Advanced fault detection of synchronous generators using stray magnetic field,” IEEE Transactions on Industrial Electronics, DOI 10.1109/TIE.2021.3118363, pp. 1-1, 2021.
[9] C. Bruzzese and G. Joksimovic, “Harmonic signatures of static eccentricities in the stator voltages and in the rotor current of no-load salient-pole synchronous generators,” IEEE Transactions on Industrial Electronics, vol. 58, no. 5, pp. 1606-1624, 2011.
[10] I. Sadeghi, H. Ehya, and J. Faiz, “Analytic method for eccentricity fault diagnosis in salient-pole synchronous generators,” in IEEE OPTIM ACEMP, pp. 261-267. IEEE, 2017.
[11] M. Valavi, K. G. J″A,rstad, and A. Nysveen, “Electromagnetic analysis and electrical signature-based detection of rotor inter-turn faults in salient-pole synchronous machine,” IEEE Transactions on Magnetics, vol. 54, DO 10.1109/TMAG.2018.2854670, no. 9, pp. 1-9, 2018.
[12] B. Kedjar, A. Merkhouf, and K. Al-Haddad, “Large synchronous machines diagnosis based on air-gap and stray fluxes—an overview,” in 2020 International Conference on Electrical Machines (ICEM), vol. 1, DOI 10.1109/ICEM49940.2020.9270868, pp. 1384-1389, 2020.
[13] S. B. Lee, G. C. Stone, J. Antonino-Daviu, K. N. Gyftakis, E. G. Strangas, P. Maussion, and C. A. Platero, “Condition monitoring of industrial electric machines: State of the art and future challenges,” IEEE Industrial Electronics Magazine, vol. 14, DOI 10.1109/MIE.2020.3016138, no. 4, pp. 158-167, 2020.
[14] C. Jiang, S. Li, and T. G. Habetler, “A review of condition monitoring of induction motors based on stray flux,” in 2017 IEEE Energy Conversion Congress and Exposition (ECCE), pp. 5424-5430, 2017.
[15] G. Capolino, R. Romary, H. HA″ ©nao, and R. Pusca, “State of the art on stray flux analysis in faulted electrical machines,” in 2019 IEEE Workshop on Electrical Machines Design, Control and Diagnosis (WEMDCD), vol. 1, DOI 10.1109/WEMDCD.2019.8887805, pp. 181-187, 2019.
[16] I. Zamudio-Ramirez, R. A. A. Osornio-Rios, J. A. Antonino-Daviu, H. Razik, and R. d. J. Romero-Troncoso, “Magnetic flux analysis for the condition monitoring of electric machines: A review,” IEEE Transactions on Industrial Informatics, DOI 10.1109/TII.2021.3070581, pp. 1-1, 2021.
[17] Y. He, Z. Zhang, W. Tao, X. Wang, D. Gerada, C. Gerada, and P. Gao, “A new external search coil based method to detect detailed static air-gap eccentricity position in non-salient pole synchronous generators,” IEEE Transactions on Industrial Electronics, DOI 10.1109/TIE.2020.3003635, pp. 1-1, 2020.
[18] M. Cuevas, R. Romary, J. Lecointe, F. Morganti, and T. Jacq, “Noninvasive detection of winding short-circuit faults in salient pole synchronous machine with squirrel-cage damper,” IEEE Transactions on Industry Applications, vol. 54, no. 6, pp. 5988-5997, 2018.
[19] M. Cuevas, R. Romary, J. Lecointe, and T. Jacq, “Non-invasive detection of rotor short-circuit fault in synchronous machines by analysis of stray magnetic field and frame vibrations,” IEEE Transactions on Magnetics, vol. 52, no. 7, pp. 1-4, 2016.
[20] J. Yun, S. B. Lee, M. ̌ Sa ̌ si′c, and G. C. Stone, “Reliable flux-based detection of field winding failures for synchronous generators,” IEEE Transactions on Energy Conversion, vol. 34, no. 3, pp. 1715-1718, 2019.
[21] H. Ehya and A. Nysveen, “Pattern recognition of interturn short circuit fault in a synchronous generator using magnetic flux,” IEEE Transactions on Industry Applications, vol. 57, DOI 10.1109/TIA.2021.3072881, no. 4, pp. 3573-3581, 2021.
[22] M. Irhoumah, R. Pusca, E. Lefevre, D. Mercier, R. Romary, and C. Demian, “Information fusion with belief functions for detection of interturn short-circuit faults in electrical machines using external flux sensors,” IEEE Transactions on Industrial Electronics, vol. 65, no. 3, pp. 2642-2652, 2017.

It will be appreciated by those skilled in the art that the invention has been illustrated by describing one or more specific embodiments thereof, but is not limited to these embodiments; many variations and modifications are possible, within the scope of the accompanying claims.

1. A method of detecting one or more faults in a synchronous machine, the method comprising:
using at least one sensor to determine a measure of a stray magnetic field generated by a synchronous machine;
processing the determined measure in order to obtain a frequency spectrum for the stray magnetic field;
analysing the frequency spectrum for the stray magnetic field in order to identify a predetermined pattern, characteristic of one or more fault conditions, within the frequency spectrum; and
determining one or more faults within the synchronous machine based on identifying the pattern.

2. The method of claim 1, wherein the one or more faults includes an inter-turn short circuit fault, or a dynamic eccentricity fault, or a short-circuit fault, or a static eccentricity fault, or a misalignment, or a demagnetization fault, or a combination of two or more such faults.

3. The method of claim 1, wherein the synchronous machine is a wound field synchronous machine or is a permanent-magnet synchronous machine or is a synchronous generator.

4. (canceled)

5. (canceled)

6. The method of claim 1, wherein the at least one sensor comprises a search coil located on or adjacent a stator core back side or a frame of the synchronous machine.

7. (canceled)

8. The method of claim 1, wherein the at least one sensor comprises at least one non-invasive sensor.

9. (canceled)

10. (canceled)

11. The method of claim 1, wherein the method is carried out during no-load or full-load operation of the synchronous machine.

12. (canceled)

13. The method of claim 1, wherein the predetermined pattern is independent of a power rating or of a topology of the synchronous machine.

14. The method of claim 1, comprising using a machine learning algorithm to identify the predetermined pattern.

15. The method of claim 1, wherein analysing the frequency spectrum comprises determining whether the frequency spectrum matches one of two or more different predetermined patterns, each predetermined pattern being characteristic of a different respective fault condition.

16. The method of claim 1, comprising signalling a detection of the one or more faults to an output device or over a network connection.

17. The method of claim 1, wherein the stray magnetic field is a combination of radial and axial magnetic fields.

18. (canceled)

19. The method of claim 1, wherein the predetermined pattern is a pattern of amplitudes of respective frequency components within the frequency spectrum.

20. (canceled)

21. The method of claim 19, wherein the predetermined pattern comprises an increasing sequence of amplitudes between a stator terminal frequency, fs, of the synchronous machine and twice fs, and a decreasing sequence of amplitudes between twice fs and three times fs, and wherein the predetermined pattern is characteristic of an inter-turn short circuit fault.

22. The method of claim 19, wherein the predetermined pattern comprises a decreasing sequence of amplitudes between a stator terminal frequency, fs, of the synchronous machine and twice fs, and an increasing sequence of amplitudes between twice fs and three times fs, and wherein the predetermined pattern is characteristic of a dynamic eccentricity fault.

23. The method of claim 19, wherein the predetermined pattern comprises the amplitudes of frequency components between a stator terminal frequency, fs, of the synchronous machine and twice fs all being within a predetermined maximum range, and wherein the predetermined pattern is characteristic of a combined inter-turn short circuit fault and dynamic eccentricity fault.

24. (canceled)

25. A fault detection system comprising a data processing apparatus configured to receive a measure of a stray magnetic field generated by a synchronous machine;
wherein the data processing apparatus is configured to:
process the received measure in order to obtain a frequency spectrum for the stray magnetic field;
analyse the frequency spectrum for the stray magnetic field in order to identify a predetermined pattern, characteristic of one or more fault conditions, within the frequency spectrum; and
determine one or more faults within the synchronous machine based on identifying the pattern.

26. (canceled)

27. The fault detection system of claim 25, wherein the data processing apparatus is or comprises a microcontroller or a field programmable gate array.

28. (canceled)

29. The fault detection system of claim 25, further comprising at least one sensor configured to determine the measure of the stray magnetic field.

30. A synchronous machine comprising the fault detection system of claim 25.

31. A non-transitory computer-readable storage medium comprising instructions that, when executed on a data processing apparatus, will cause the data processing apparatus to:
process a received measure of a stray magnetic field generated by a synchronous machine in order to obtain a frequency spectrum for the stray magnetic field;
analyse the frequency spectrum for the stray magnetic field in order to identify a predetermined pattern, characteristic of one or more fault conditions, within the frequency spectrum; and
determine one or more faults within the synchronous machine based on identifying the pattern.

32. (canceled)
